(19) United States
(12) Patent Application Publication
(10) Pub. No.: US 2020/0066861 A1
(43) Pub. Date: Feb. 27, 2020

(54) INTEGRATED CIRCUIT DEVICE

(71) Applicant: Toshiba Memory Corporation, Tokyo (JP)

(72) Inventor: Masakazu GOTO, Yokkaichi Mie (JP)

(73) Assignee: Toshiba Memory Corporation, Tokyo (JP)

(21) Appl. No.: 16/283,601

(22) Filed: Feb. 22, 2019

(30) Foreign Application Priority Data
Aug. 24, 2018 (JP) 2018-157779

(51) Int. Cl. H01L 29/49; H01L 23/522; H01L 27/12; H01L 29/786

(52) U.S. Cl. CPC H01L 29/4908; H01L 23/5226; H01L 29/78648; H01L 29/78642; H01L 27/124

(57) ABSTRACT

An integrated circuit device includes a first wiring, a second wiring, a first semiconductor portion, a second semiconductor portion, a third semiconductor portion, an insulating film, and an electrode. The third semiconductor portion is provided between the first semiconductor portion and the second semiconductor portion. The electrode has a first electrode portion and a second electrode portion. The first electrode portion is provided on a part of the third semiconductor portion with the insulating film interposed therebetween. The second electrode portion is electrically connected to the first electrode portion, located adjacent the second semiconductor portion, and provided on another part of the third semiconductor portion with the insulating film interposed therebetween. The second electrode portion has a concentration of at least one of nitrogen, oxygen, carbon, or silicon that is different from that of the first electrode portion.

### CROSS-REFERENCE TO RELATED APPLICATION

This application is based upon and claims the benefit of priority from Japanese Patent Application No. 2018-157779, filed Aug. 24, 2018, the entire contents of which are incorporated herein by reference.

### FIELD

Embodiments described herein relate generally to an integrated circuit device.

### BACKGROUND

There has been proposed an integrated circuit device in which a switching element is provided between two wirings.

### DESCRIPTION OF THE DRAWINGS

FIG. 1 is a perspective view illustrating an integrated circuit device of a first embodiment.

FIG. 2 is a perspective view illustrating a vertical TFT of the first embodiment and a structure around the vertical TFT.

FIG. 3 is a view illustrating a cross section and an impurity profile of the vertical TFT of the first embodiment.

FIG. 4 is a cross-sectional view illustrating the vertical TFT of the first embodiment.

FIG. 5A is a cross-sectional view illustrating a method of manufacturing the integrated circuit device of the first embodiment.

FIG. 5B is a cross-sectional view illustrating the method of manufacturing the integrated circuit device of the first embodiment.

FIG. 5C is a cross-sectional view illustrating the method of manufacturing the integrated circuit device of the first embodiment.

FIG. 5D is a cross-sectional view illustrating the method of manufacturing the integrated circuit device of the first embodiment.

FIG. 5E is a cross-sectional view illustrating the method of manufacturing the integrated circuit device of the first embodiment.

FIG. 5F is a cross-sectional view illustrating the method of manufacturing the integrated circuit device of the first embodiment.

FIG. 6 is a cross-sectional view for explaining an operation of the vertical TFT of the first embodiment.

FIG. 7 is a cross-sectional view illustrating a vertical TFT of a second embodiment.

FIG. 8 is a cross-sectional view illustrating a method of manufacturing the integrated circuit device of the second embodiment.

FIG. 9 is a cross-sectional view illustrating a vertical TFT of a third embodiment.

FIG. 10 is a view illustrating an example of a combination of a first element and a second element of the embodiment.

FIG. 11 is a view illustrating an example of a combination of a third element and a fourth element of the embodiment.

### DETAILED DESCRIPTION

At least one embodiment provides an integrated circuit device capable of improving electrical characteristics.

In general, according to at least one embodiment, an integrated circuit device includes a first wiring, a second wiring, a first semiconductor portion, a second semiconductor portion, a third semiconductor portion, an insulating film, and an electrode. The first semiconductor portion is electrically connected to the first wiring and has a first conductivity type. The second semiconductor portion is electrically connected to the second wiring and has the first conductivity type. The third semiconductor portion is provided between the first semiconductor portion and the second semiconductor portion and has a second conductivity type. The insulating film is provided on at least a part of the first semiconductor portion, at least a part of the second semiconductor portion, and the third semiconductor portion. The electrode has a first electrode portion and a second electrode portion. The first electrode portion is provided on a part of the third semiconductor portion with the insulating film interposed therebetween. The second electrode portion is electrically connected to the first electrode portion, located in the vicinity of the second semiconductor portion with respect to the first electrode portion, and provided on another part of the third semiconductor portion with the insulating film interposed therebetween. The second electrode portion has a concentration of at least one of nitrogen, oxygen, carbon, and silicon which is different from that of the first electrode portion.

Hereinafter, an integrated circuit device of an embodiment will be described with reference to the drawings. In the following description, the configurations, which have the same or similar functions, are denoted by the same reference numerals. Further, repeated descriptions of the configurations are sometimes omitted. The drawings are schematic or conceptual, and relationships between thicknesses and widths of portions, ratios between sizes of portions, and the like are not necessarily the same as the actual values thereof.

As used herein, the term “connection” is intended to include not only physical connection but also electrical connection. That is, the term “connection” is intended to include not only a case where two members are in direct contact with each other but also a case where another member is interposed between the two members. As used herein, the terms “overlap” and “face” are intended to include not only a case where two members directly face each other but also a case where another member is present between the two members. In addition, the terms “overlap” and “face” are also intended to include a case where the two members partially face each other. In addition, the term “provided on XX” (XX is any element) does not mean the provision above XX in the direction of gravity.

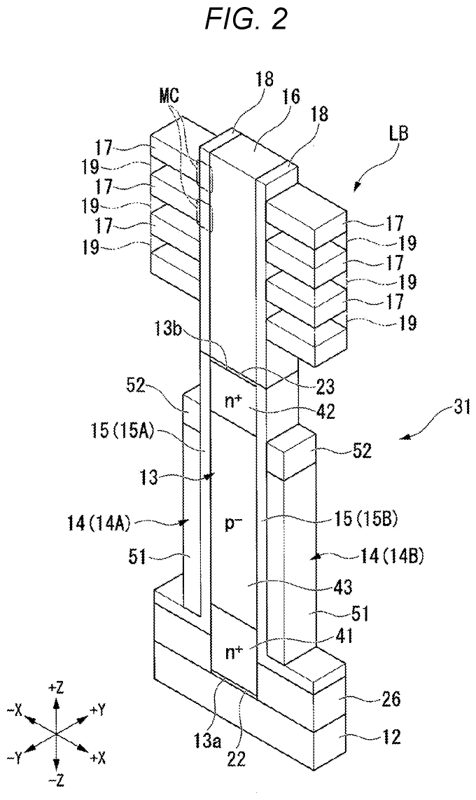

First, a +X direction, a −X direction, a +Y direction, a −Y direction, a +Z direction, and a −Z direction are defined. The +X direction is a direction from one gate electrode 14 (first gate electrode 14A) toward a silicon member 13 to be described below (see FIG. 2). The +X direction is an example of a “second direction.” The −X direction is a direction opposite to the +X direction. The “X direction” will be simply used when the +X direction and the −X direction are not distinguished. The +Y direction and the −Y direction are directions intersecting (e.g., approximately orthogonal to) the X direction. The +Y direction and the −Y direction are directions opposite to each other. The “Y direction” will be simply used when the +Y direction and the −Y direction are not distinguished. The +Y direction is an example of a “third direction.” The +Z direction and the −Z direction are directions intersecting (e.g., approximately orthogonal to) the X direction and the Y direction. The +Z direction is a direction from a first semiconductor portion 41 toward a second semiconductor portion 42 to be described below (see FIG. 2). The +Z direction is an example of a “first direction.” The −Z direction is a direction opposite to the +Z direction. The “Z direction” will be simply used when the +Z direction and the −Z direction are not distinguished. In the present specification, sometimes, the “+Z direction” is referred to as “upward,” and the “−Z direction” is referred to as “downward.” However, these expressions are used for convenience and do not correspond to the direction of gravity.

### First Embodiment

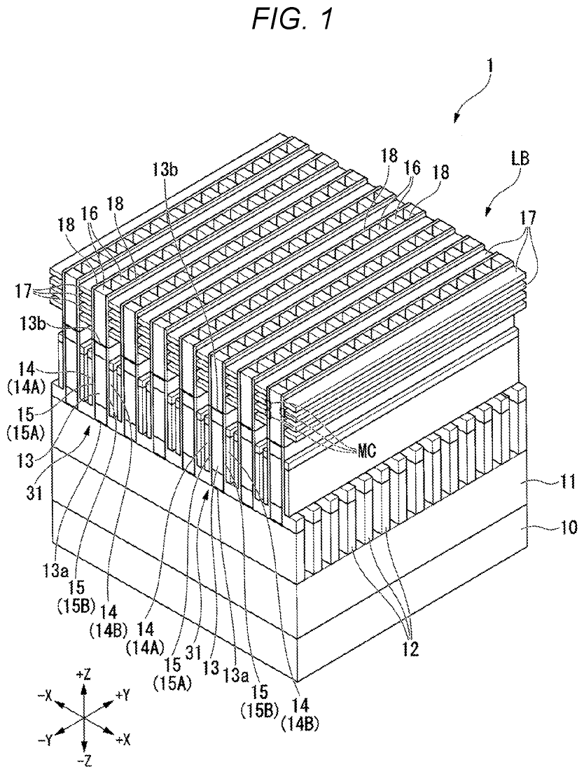

An integrated circuit device 1 of a first embodiment will be described with reference to FIGS. 1 to 6. The integrated circuit device 1 is, for example, a resistance variable semiconductor storage device. However, the “integrated circuit device” disclosed in the present specification may be a semiconductor storage device other than the resistance variable semiconductor storage device or may be a device different from the storage device.

FIG. 1 is a perspective view illustrating the integrated circuit device 1 of the present embodiment. In FIG. 1, several insulating films and contacts 24 (to be described below) are omitted. The integrated circuit device 1 has, for example, a silicon substrate 10, an interlayer insulating film 11, a plurality of global bit lines 12, a plurality of silicon members 13, a plurality of gate electrodes 14, a plurality of gate insulating films 15, a plurality of local bit lines 16, a plurality of word lines 17, a plurality of resistance change films 18, and a plurality of interlayer insulating films 19 (see FIG. 2).

The silicon substrate 10 is formed in a plate shape in an X direction and a Y direction. The silicon substrate 10 is an example of a “substrate.” The interlayer insulating film 11 is provided on the silicon substrate 10. The interlayer insulating film 11 is made of, for example, silicon oxide (SiO). Circuit elements (not illustrated) such as a CMOS transistor are formed on an upper layer portion of the silicon substrate 10 and a lower layer portion of the interlayer insulating film 11. Conductive members (not illustrated) such as wirings and via are formed in the interlayer insulating film 11. Therefore, a drive circuit is formed in the silicon substrate 10 and the interlayer insulating film 11.

The plurality of global bit lines 12 are provided on, for example, the interlayer insulating film 11. The global bit line 12 is made of, for example, a conductive material such as tungsten (W). The global bit line 12 is an example of a “first wiring.” The plurality of global bit lines 12 are disposed at intervals in the Y direction and extend in the X direction so as to be approximately parallel to one another. The definition “the global bit line 12 extends in the X direction” means that the length of the global bit line 12 in the X direction is greater than dimensions of the global bit line 12 in the Y direction and a Z direction. This definition equally applies to other constituent elements and other directions.

The plurality of silicon members 13 are provided above the plurality of global bit lines 12. Each of the silicon members 13 is formed in an approximately rectangular parallelepiped shape having a length in the Z direction. The plurality of silicon members 13 are arranged in a matrix configuration at intervals in the X direction and the Y direction. A barrier metal layer 22 (see FIG. 2), which is made of, for example, titanium nitride (TiN), is provided between a lower end 13a of the silicon member 13 and the global bit line 12. The lower end 13a of the silicon member 13 is connected to the global bit line 12 through the barrier metal layer 22. For example, the lower ends 13a of the plurality of silicon members 13, which are arranged in the X direction, are connected in common to the one global bit line 12.

The plurality of gate electrodes 14 include first gate electrodes 14A located at a side in the −X direction and second gate electrodes 14B located at a side in the +X direction with respect to the one silicon member 13. In the following description, the term “gate electrode 14” is simply used in a case where the first gate electrode 14A and the second gate electrode 14B are not distinguished from each other. The gate electrode 14 is an example of an “electrode.” The respective gate electrodes 14 extend in the Y direction and face the plurality of silicon members 13 arranged in the Y direction.

The plurality of gate insulating films 15 include first gate insulating films 15A which are provided between the first gate electrodes 14A and the silicon members 13, and second gate insulating films 15B which are provided between the second gate electrodes 14B and the silicon members 13. In the following description, the term “gate insulating film 15” is simply used in a case where the first gate insulating film 15A and the second gate insulating film 15B are not distinguished from each other. The gate insulating film 15 is an example of a “first insulating film.” The gate insulating film 15 is made of, for example, silicon oxide (SiO2) or the like. The respective gate insulating films 15 extend in the Y direction and face the plurality of silicon members 13 arranged in the Y direction.

In at least one embodiment, one n-channel type vertical thin film transistor (TFT) 31 is formed by the one silicon member 13, the pair of gate electrodes 14A and 14B with the silicon member 13 interposed therebetween, and the gate insulating films 15A and 15B provided between the silicon member 13 and the gate electrodes 14A and 14B. The vertical TFT 31 is a switching element that allows a current to flow and cuts off the flow of the current between the global bit line 12 and the local bit line 16 to be described below. Further, instead of the aforementioned configuration, the vertical TFT 31 may be formed by the one silicon member 13, the one gate electrode 14A, and the one gate insulating film 15A. The configuration of the vertical TFT 31 will be described in detail below.

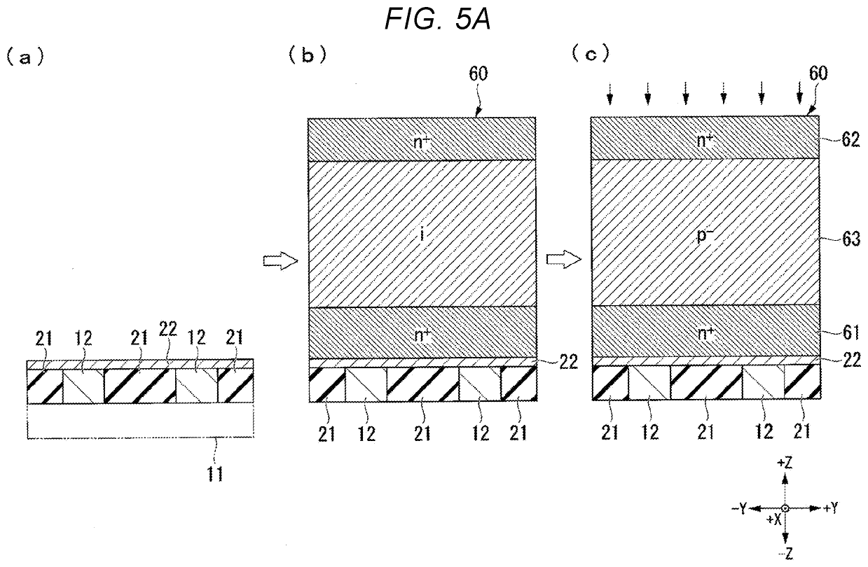

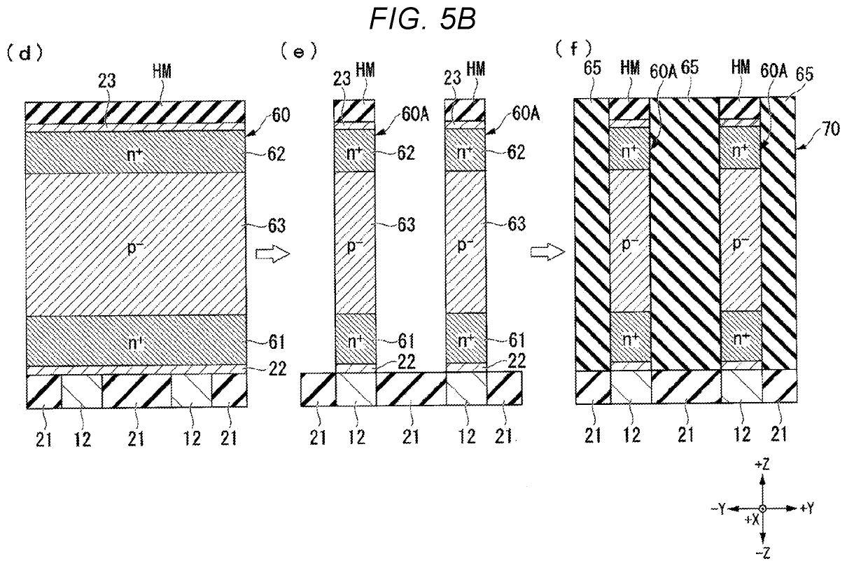

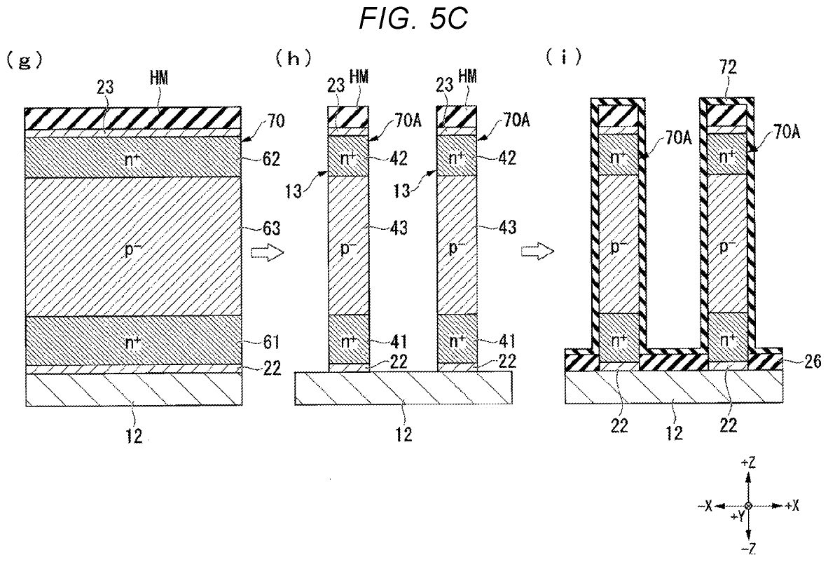

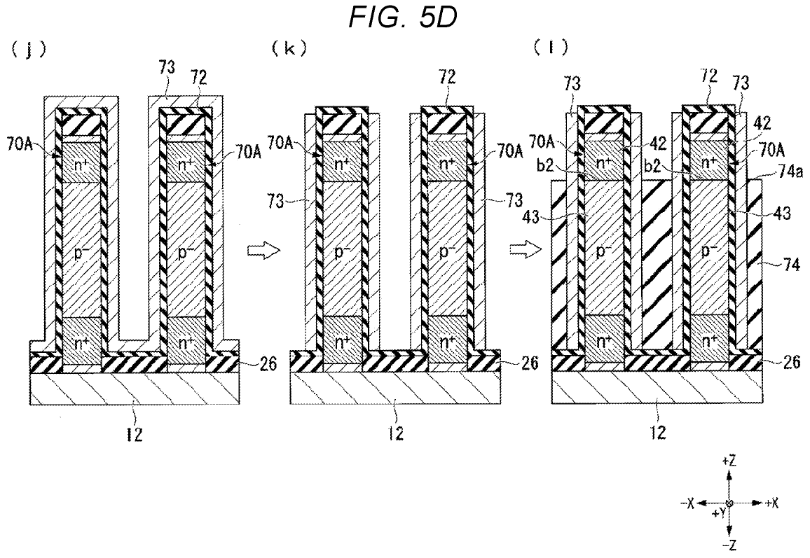

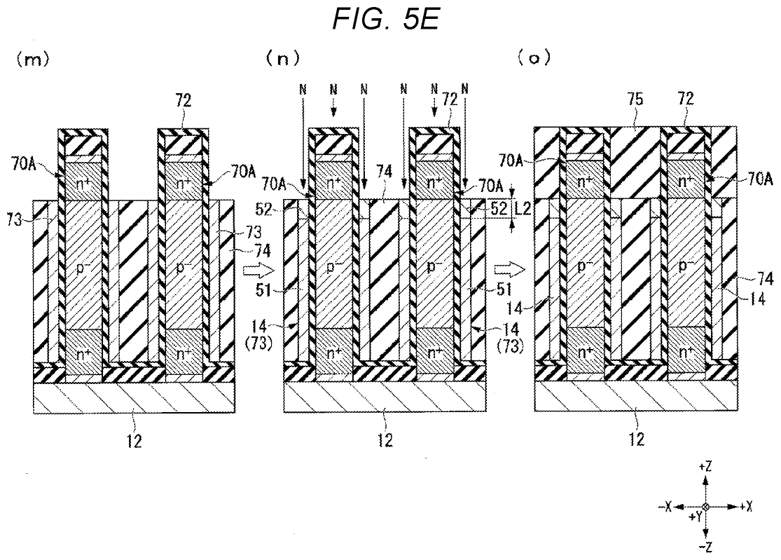

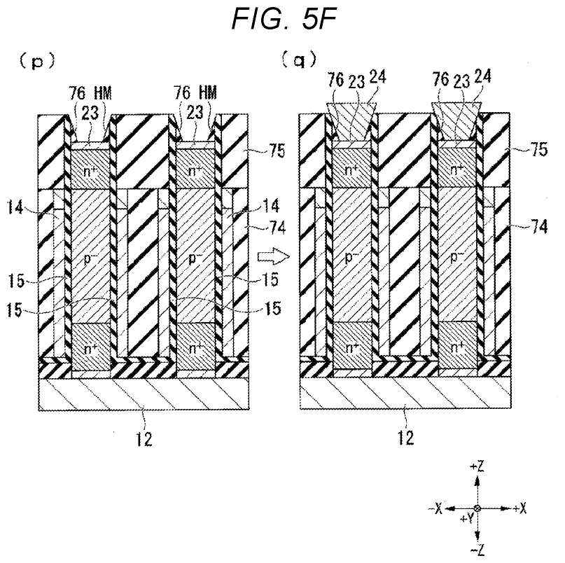

The plurality of local bit lines 16 are provided above the plurality of silicon members 13. The local bit line 16 is made of, for example, a conductive material such as titanium nitride. The local bit line 16 is an example of a “second wiring.” The plurality of local bit lines 16 are arranged in a matrix configuration at intervals in the X direction and the Y direction and located in a region directly above the silicon member 13. Each of the local bit lines 16 is formed, for example, in an approximately quadrangular column shape and extends in the Z direction. A barrier metal layer 23, which is made of, for example, titanium nitride, and a contact 24, which is made of, for example, tungsten, are provided between the local bit line 16 and the silicon member 13 (see FIG. 5F). The local bit line 16 is connected to an upper end 13b of the silicon member 13 with the barrier metal layer 23 and the contact 24 interposed therebetween.

The plurality of word lines 17 are provided between the local bit lines 16 arranged in the X direction, respectively. The plurality of word lines 17, which are disposed between the two local bit lines 16 adjacent to each other in the X direction, are disposed at intervals in the Z direction and extend in approximately parallel with each other in the Y direction. The word line 17 is made of, for example, a conductive material such as titanium nitride. The word line 17 is an example of a “third wiring.”

The resistance change films 18 are provided between the local bit lines 16 and the plurality of word lines 17. A band structure and a resistance state of the resistance change film 18 are changed by an applied voltage or an applied current. Therefore, memory cells MC are formed with the resistance change film 18 interposed therebetween at portions where the local bit lines 16 and the word line 17 intersect one another. The memory cells MC are arranged in a three-dimensional matrix configuration at intervals in the X direction, the Y direction, and the Z direction. The integrated circuit device 1 stores information by changing the resistance states of the respective memory cells MC.

The plurality of interlayer insulating films 19 (see FIG. 2) are provided between the word lines 17 arranged in the Z direction, respectively. The interlayer insulating film 19 is made of, for example, silicon oxide. The interlayer insulating film 19 is an example of a “second insulating film.” The plurality of word lines 17 and the plurality of interlayer insulating films 19 are alternately stacked in the Z direction. Therefore, the integrated circuit device 1 has a stacked body LB including the plurality of word lines 17 and the plurality of interlayer insulating films 19.

Next, a configuration of each of the parts of the vertical TFT 31 of the present embodiment will be described in detail.

FIG. 2 is a perspective view illustrating the vertical TFT 31 and a structure around the vertical TFT 31. In FIG. 2, the several insulating films and the contacts 24 are also omitted.

First, the silicon member 13 will be described.

The silicon member 13 has, for example, a first semiconductor portion 41, a second semiconductor portion 42, and a third semiconductor portion 43.

The first semiconductor portion 41 includes the lower end 13a of the silicon member 13 which is located at a side of the global bit line 12 with respect to the local bit line 16 in the silicon member 13. The first semiconductor portion 41 is connected to the global bit line 12, for example, through the barrier metal layer 22. The first semiconductor portion 41 includes an impurity which is a donor, and the first semiconductor portion 41 is an n type (e.g., n+ type) as a conductivity type. The n type is an example of a “first conductivity type.” The “donor” is an element that has more valence electrons than a tetravalent element, and the donor is, for example, a pentavalent element. In the present embodiment, an example in which phosphorus (P) is used as the donor will be described.

The second semiconductor portion 42 includes the upper end 13b of the silicon member 13 which is located at a side of the local bit line 16 with respect to the global bit line 12 in the silicon member 13. The second semiconductor portion 42 is connected to the local bit line 16, for example, through the barrier metal layer 23 and the contact 24 (see FIG. 5F). The second semiconductor portion 42 includes an impurity which is a donor, and the second semiconductor portion 42 is an n type (e.g., n+ type) as a conductivity type.

The third semiconductor portion 43 is provided in the Z direction between the first semiconductor portion 41 and the second semiconductor portion 42. A lower portion of the third semiconductor portion 43 is connected to the first semiconductor portion 41. An upper portion of the third semiconductor portion 43 is connected to the second semiconductor portion 42. The third semiconductor portion 43 includes an impurity which is an acceptor, and the third semiconductor portion 43 is a p type (e.g., p− type) as a conductivity type. The p type is an example of a “second conductivity type.” The “acceptor” is an element that has less valence electrons than a tetravalent element, and the acceptor is, for example, a trivalent element. In the present embodiment, an example in which boron (B) is used as the acceptor will be described.

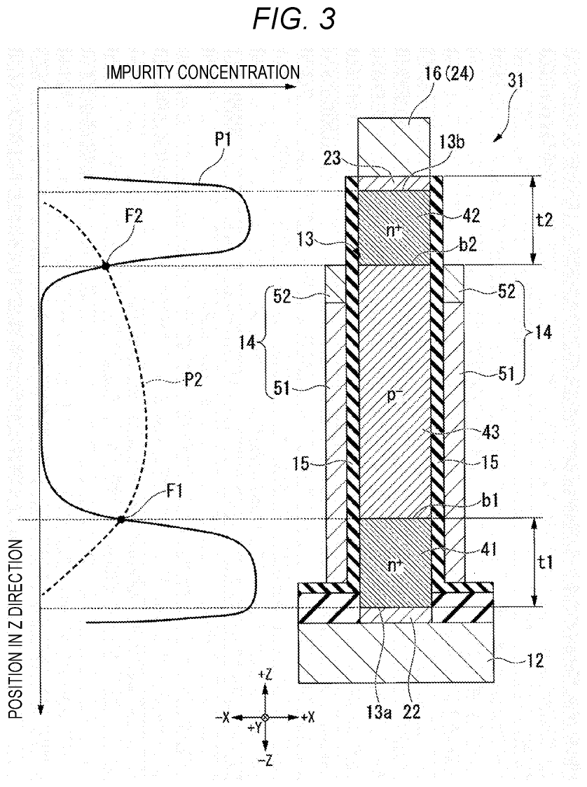

FIG. 3 is a view illustrating a cross section of the vertical TFT 31 and an impurity profile in the present embodiment. In the impurity profile in FIG. 3, a vertical axis indicates a position in the Z direction, and a horizontal axis indicates impurity concentration. In the present specification, based on a magnitude relationship between the concentration of the donor and the concentration of the acceptor, a boundary b1 between the third semiconductor portion 43 and the first semiconductor portion 41 and a boundary b2 between the third semiconductor portion 43 and the second semiconductor portion 42 are defined. That is, positions F1 and F2 at which a concentration profile P1 of the phosphorus which is the donor and a concentration profile P2 of the boron which is the acceptor intersect each other in the Z direction correspond to the boundary b1 between the third semiconductor portion 43 and the first semiconductor portion 41 and the boundary b2 between the third semiconductor portion 43 and the second semiconductor portion 42, respectively. In other words, portions where the concentration of the phosphorus is higher than the concentration of the boron in the silicon member 13 are the first semiconductor portion 41 and the second semiconductor portion 42. Meanwhile, a portion where the concentration of the boron is higher than the concentration of the phosphorus in the silicon member 13 is the third semiconductor portion 43. In at least one embodiment, a thickness t2 of the second semiconductor portion 42 in the Z direction is smaller than a thickness t1 of the first semiconductor portion 41 in the Z direction.

Next, the gate insulating film 15 will be described.

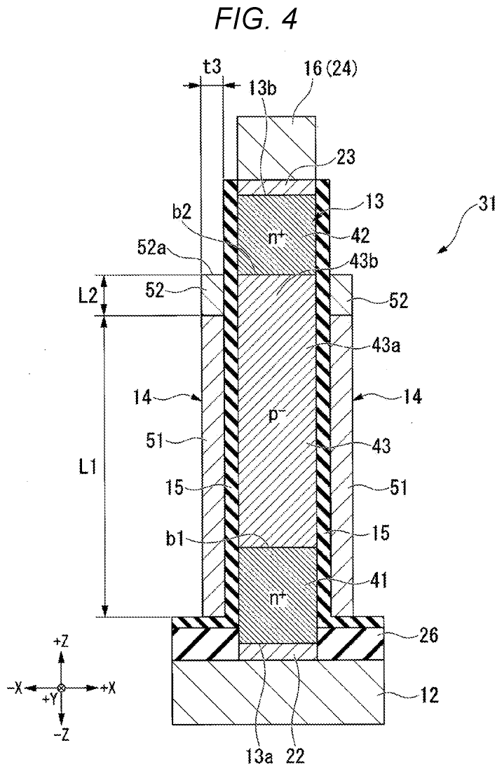

FIG. 4 is a cross-sectional view illustrating the vertical TFT 31 of the present embodiment. The gate insulating film 15 is adjacent to a side in the −X direction or a side in the +X direction of the silicon member 13. The gate insulating film 15 is provided on at least a part of the first semiconductor portion 41, at least a part of the second semiconductor portion 42, and the third semiconductor portion 43. The gate insulating film 15 faces, in the X direction, at least a part of the first semiconductor portion 41, at least a part of the second semiconductor portion 42, and the third semiconductor portion 43, such that the gate insulating film 15 is in contact with the first to third semiconductor portions 41, 42, and 43.

Next, the gate electrode 14 will be described.

The gate electrode 14 is adjacent to a side in the −X direction and a side in the +X direction of the gate insulating film 15. The gate electrode 14 includes a first electrode portion 51 and a second electrode portion 52. The first electrode portion 51 and the second electrode portion 52 extend in the Y direction.

The first electrode portion 51 overlaps, in the X direction, a part of the third semiconductor portion 43 (a first portion 43a of the third semiconductor portion 43) with the gate insulating film 15 interposed therebetween. In at least one embodiment, the first electrode portion 51 forms a portion of the gate electrode 14 other than the upper portion of the gate electrode 14 and overlaps a part of the third semiconductor portion 43 and at least a part of the first semiconductor portion 41 with the gate insulating film 15 interposed therebetween. That is, the first electrode portion 51 is provided on a part of the third semiconductor portion 43 and at least a part of the first semiconductor portion 41 with the gate insulating film 15 interposed therebetween. An insulating film 26 is provided between the first electrode portion 51 and the global bit line 12. The insulating film 26 overlaps, in the X direction, a part of the first semiconductor portion 41. As the insulating film 26 is provided, an insulation distance is ensured between the first electrode portion 51 and the global bit line 12.

The first electrode portion 51 is made of a first element. In the present embodiment, the first electrode portion 51 is made of tantalum (Ta) which is an example of the first element.

The second electrode portion 52 is provided above the first electrode portion 51 in the Z direction and electrically connected to the first electrode portion 51. The second electrode portion 52 is located in the vicinity of the second semiconductor portion 42 in the Z direction in comparison with the first electrode portion 51. The second electrode portion 52 forms the upper portion of the gate electrode 14. The second electrode portion 52 is provided continuously from the first electrode portion 51 in the Z direction and connected to the first electrode portion 51. The configuration “the second electrode portion 52 is connected to the first electrode portion 51” means that no insulating film is present between the first electrode portion 51 and the second electrode portion 52. The second electrode portion 52 overlaps, in the X direction, another part of the third semiconductor portion 43 (a second portion 43b of the third semiconductor portion 43) with the gate insulating film 15 interposed therebetween. That is, the second electrode portion 52 is provided on another part of the third semiconductor portion 43 with the gate insulating film 15 interposed therebetween. The second portion 43b is an upper end of the third semiconductor portion 43 connected to the second semiconductor portion 42.

In at least one embodiment, the second electrode portion 52 does not overlap, in the X direction, the second semiconductor portion 42. That is, an upper end 52a of the second electrode portion 52 is located at approximately the same position in the Z direction as the boundary b2 between the third semiconductor portion 43 and the second semiconductor portion 42 or located below the boundary b2.

The second electrode portion 52 includes at least one of nitrogen (N), oxygen (O), carbon (C), or silicon (Si) in addition to the first element that forms the first electrode portion 51. That is, the second electrode portion 52 is formed by a composition (compound) created by coupling at least one of nitrogen, oxygen, carbon, and silicon to the first element. In another expression, the second electrode portion 52 has higher concentration of at least one of nitrogen, oxygen, carbon, and silicon than the first electrode portion 51.

In at least one embodiment, the vertical TFT 31 is an n-channel type transistor. In this case, the second electrode portion 52 includes a second element that forms a composition, which has a lower work function than the first element, by coupling one of nitrogen, oxygen, carbon, or silicon to the first element. For example, in a case where the first element is tantalum, an example of the second element is nitrogen. In this case, the second electrode portion 52 is made of tantalum nitride (TaN).

In at least one embodiment, the length L2 of the second electrode portion 52 in the Z direction is shorter than the length L1 of the first electrode portion 51 in the Z direction. For example, the length L2 of the second electrode portion 52 in the Z direction is equal to or shorter than a half of the length L1 of the first electrode portion 51 in the Z direction. Meanwhile, the length L2 of the second electrode portion 52 in the Z direction is greater than a thickness t3 of the second electrode portion 52 in the X direction. The length L2 of the second electrode portion 52 in the Z direction is, for example, 20 nm or more.

Next, an example of a method of manufacturing the integrated circuit device 1 will be described, focusing on a method of forming the vertical TFT 31. FIGS. 5A to 5F are cross-sectional views illustrating a method of manufacturing the integrated circuit device 1 of at least one embodiment. Here, an example in which the second electrode portion 52 includes nitrogen will be described.

In the method of manufacturing the integrated circuit device 1, the interlayer insulating film 11 is formed on the silicon substrate 10 first, and the drive circuit is formed in the silicon substrate 10 and the interlayer insulating film 11.

Next, as illustrated in part (a) of FIG. 5A, the plurality of global bit lines 12 and the plurality of insulating films 21 are formed on the interlayer insulating film 11. Next, the barrier metal layer 22 is formed on the global bit line 12 and the insulating film 21.

Next, as illustrated in part (b) of FIG. 5A, a silicon film 60 is formed on the barrier metal layer 22. The silicon film 60 is formed, for example, as an impurity, which is a donor, for example, phosphorus is introduced into a required part and silicon is accumulated by a chemical vapor deposition (CVD) method.

Next, as illustrated in part (c) of FIG. 5A, an impurity, which is an acceptor, for example, boron is ion-implanted, such that an i-type layer in the silicon film 60 is changed to a p-type layer. Next, an annealing treatment is performed, such that phosphorus and boron are diffused and activated. Therefore, a first semiconductor layer 61, a second semiconductor layer 62, and a third semiconductor layer 63 are formed.

Next, as illustrated in part (d) of FIG. 5B, the barrier metal layer 23 is formed on the silicon film 60. Next, a hard mask HM, which is made of, for example, silicon nitride (SiN), is formed on the barrier metal layer 23.

Next, as illustrated in part (e) of FIG. 5B, the hard mask HM is processed by a lithography method and a reactive ion etching (RIE) method, and the hard mask HM remains only in a region directly above the global bit line 12. Next, the silicon film 60 is processed by the RIE method that uses the processed hard mask HM as a mask, and the silicon film 60 is divided into plurality of silicon plates 60A.

Next, as illustrated in part (f) of FIG. 5B, an insulating material, which is made of, for example, silicon oxide, is embedded between the plurality of silicon plates 60A, and insulating films 65 are formed. Therefore, an intermediate structure 70 in which the silicon plates 60A and the insulating films 65 are alternately arranged in the Y direction is created.

Part (g) of FIG. 5C is a view illustrating the intermediate structure 70 illustrated in part (f) of FIG. 5B when viewed in another direction. Next, as illustrated in part (h) of FIG. 5C, the intermediate structure 70 is processed by the lithography method and the RIE method and divided into plurality of columnar intermediate structures 70A. In this case, the respective silicon plates 60A are divided into the plurality of columnar silicon members 13, such that the first to third semiconductor layers 61, 62, and 63 become the first to third semiconductor portions 41, 42, and 43.

Next, as illustrated in part (i) of FIG. 5C, etch back is performed by depositing, for example, silicon oxide between the plurality of intermediate structures 70A, such that the insulating film 26 is formed on the global bit line 12. Next, an insulating film 72, which becomes the gate insulating film 15, is formed by depositing a silicon oxide film on the insulating film 26 and the intermediate structure 70A.

Next, as illustrated in part (j) of FIG. 5D, an electrode film 73, which becomes the gate electrode 14, is formed on the insulating film 72 by depositing a conductive material. Next, as illustrated in part (k) of FIG. 5D, the electrode film 73 is removed from the upper side of the intermediate structure 70A by the RIE method. Next, as illustrated in part (1) of FIG. 5D, an insulating material is embedded in a region except for the upper sides of the intermediate structure 70A and the electrode film 73, and an insulating portion 74 is formed. The insulating material is, for example, tetraethyl orthosilicate (TEOS). In this case, an upper surface 74a of the insulating portion 74 in the Z direction is located at approximately the same height as the boundary b2 between the third semiconductor portion 43 and the second semiconductor portion 42, or the position of the upper surface 74a of the insulating portion 74 in the Z direction is adjusted to a position below the boundary b2.

Next, as illustrated in part (m) of FIG. 5E, the electrode film 73, which is located above the insulating portion 74, is removed, for example, by the RIE method.

Next, as illustrated in part (n) of FIG. 5E, a process of introducing nitrogen to the upper portion of the electrode film 73 is performed. Here, in the configuration in at least one embodiment, an upper side of the intermediate structure 70A in this case is vacant. For this reason, it is possible to comparatively easily introduce nitrogen to the upper portion of the electrode film 73. Examples of the process of introducing nitrogen may include ion implantation of nitrogen ions or an annealing treatment in a nitrogen atmosphere. Therefore, on the upper portion of the electrode film 73, nitrogen is coupled to metal that forms the electrode film 73. Therefore, the gate electrode 14, which has the second electrode portion 52 that has higher nitrogen concentration than the first electrode portion 51, is formed. In this case, the length L2 of the second electrode portion 52 in the Z direction may be adjusted by adjusting an acceleration voltage for the ion implantation or time of the annealing treatment. Further, in the present embodiment, nitrogen may or may not be introduced to the insulating film 72 that becomes the gate insulating film 15. An example in which nitrogen is introduced to the insulating film 72 will be described again as a second embodiment.

Next, as illustrated in part (o) of FIG. 5E, an insulating material is supplied onto the insulating portion 74 and the gate electrode 14, and an insulating portion 75 is formed. Next, as illustrated in part (p) of FIG. 5F, the upper portion of the insulating film 72 is removed by the RIE method, such that the insulating film 72 becomes the gate insulating film 15. In addition, holes 76 are provided in the hard mask HM by the lithography method and the RIE method. Next, as illustrated in part (q) of FIG. 5F, the contacts 24 are provided in the holes 76. Therefore, a lower portion of the integrated circuit device 1 is formed.

Thereafter, conductive films and insulating films are alternately stacked on the lower portion of the integrated circuit device 1 such that a stacked body is formed, and the stacked body is processed such that the stacked body LB including the plurality of word lines 17 and the plurality of interlayer insulating films 19 is formed. In addition, the resistance change film 18 and the local bit line 16 are provided between the word lines 17. Therefore, the integrated circuit device 1 is manufactured.

Next, an operation of the integrated circuit device 1 will be described.

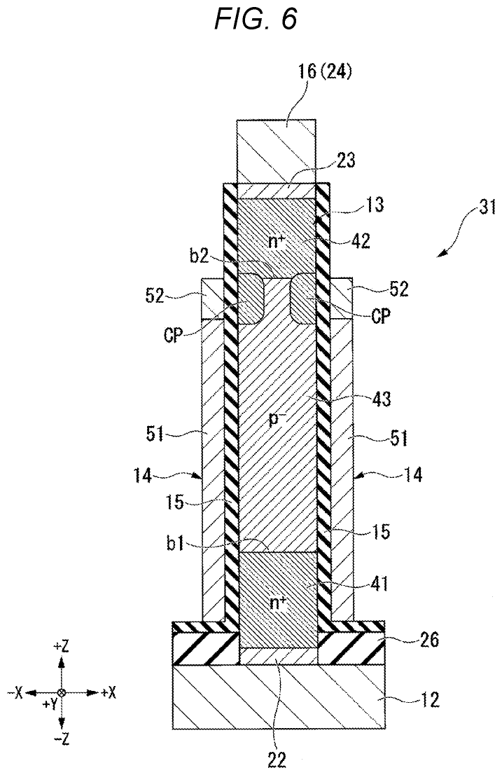

FIG. 6 is a cross-sectional view for explaining an operation of the integrated circuit device 1. In at least one embodiment, the gate electrode 14 has the first electrode portion 51 and the second electrode portion 52 that has a lower work function than the first electrode portion 51. In this case, when a voltage is applied to the gate electrode 14, the second electrode portion 52 comes into an ON state first in comparison with the first electrode portion 51, and an n-type channel portion CP formed by the second electrode portion 52 is formed at an upper end of the third semiconductor portion 43. Here, since the second electrode portion 52 has a lower work function than the first electrode portion 51, a comparatively large fringe electric field may be applied. For this reason, the n-type channel portion CP, which is formed by the second electrode portion 52, is more easily expanded in the +Z direction and the −Z direction than the upper end and the lower end of the second electrode portion 52. For this reason, the n-type channel portion CP, which is formed by the second electrode portion 52, may be connected to the second semiconductor portion 42 in the Z direction even though the second electrode portion 52 does not overlap the second semiconductor portion 42. Further, the first electrode portion 51 comes into the ON state after the n-type channel portion CP is formed by the second electrode portion 52, such that the gate electrode 14 may form an n-type channel that connects the first semiconductor portion 41 and the second semiconductor portion 42.

According to the integrated circuit device 1 having the aforementioned configuration, it is possible to improve electrical characteristics. For example, improvement in plurality of electrical characteristics of the integrated circuit device 1 is expected. Examples of the electrical characteristics may include breakdown voltage characteristics between a source and a drain of the vertical TFT 31 first. To improve the breakdown voltage characteristics, it is conceivable that at least one of a thickness of the first semiconductor portion 41 in the Z direction and a thickness of the second semiconductor portion 42 is decreased and a distance between the first semiconductor portion 41 and the second semiconductor portion 42 is increased.

However, when the thickness of the second semiconductor portion 42 in the Z direction is decreased, a width of the gate electrode 14, which overlaps the second semiconductor portion 42, is decreased, and a current flowing through the vertical TFT 31 when the vertical TFT 31 operates (ON current) is decreased. Therefore, it is conceivable that the width of the gate electrode 14, which overlaps the second semiconductor portion 42, is ensured by decreasing the thickness of the second semiconductor portion 42 in the Z direction and increasing the length of the gate electrode 14 in the Z direction.

However, when the length of the gate electrode 14 in the Z direction is increased, an insulation distance between the gate electrode 14 and the local bit line 16 is decreased, and a likelihood that a short circuit will occur between the gate electrode 14 and the local bit line 16 is increased.

Therefore, in at least one embodiment, the gate electrode 14 has the first electrode portion 51 and the second electrode portion 52 that has a lower work function than the first electrode portion 51. According to this configuration, when a voltage is applied to the gate electrode 14, the n-type channel portion CP, which is connected to the second semiconductor portion 42, is formed by the second electrode portion 52. For this reason, it is possible to inhibit a decrease in the ON current of the vertical TFT 31 even in the case where the width of the gate electrode 14, which overlaps the second semiconductor portion 42, is small or the gate electrode 14 does not overlap the second semiconductor portion 42. Therefore, improvement in breakdown voltage characteristics of the vertical TFT 31, inhibition of a reduction in ON current of the vertical TFT 31, and inhibition of occurrence of a short circuit between the gate electrode 14 and the local bit line 16 can be achieved.

In at least one embodiment, the gate electrode 14 includes not only the second electrode portion 52 having a low work function but also the first electrode portion 51 that has a higher work function than the second electrode portion 52. According to this configuration, it is possible to decrease a leakage current that flows when the vertical TFT 31 is in an OFF state in comparison with the case where the gate electrode 14 is formed only by the second electrode portion 52.

In at least one embodiment, the second electrode portion 52 is provided above the first electrode portion 51. According to this configuration, it is possible to form the first electrode portion 51 and the second electrode portion 52 without providing an insulating film between the first electrode portion 51 and the second electrode portion 52. For this reason, it is possible to inhibit a potential barrier (discontinuous point) from being formed in the n-type channel in comparison with the case where the insulating film is provided between the first electrode portion 51 and the second electrode portion 52. Therefore, it is possible to further inhibit a decrease in ON current of the vertical TFT 31.

### Second Embodiment

Next, a second embodiment will be described. The second embodiment differs from the first embodiment in that nitrogen is also introduced to the gate insulating film 15. Further, the configurations except for the following configurations are identical to those in the first embodiment.

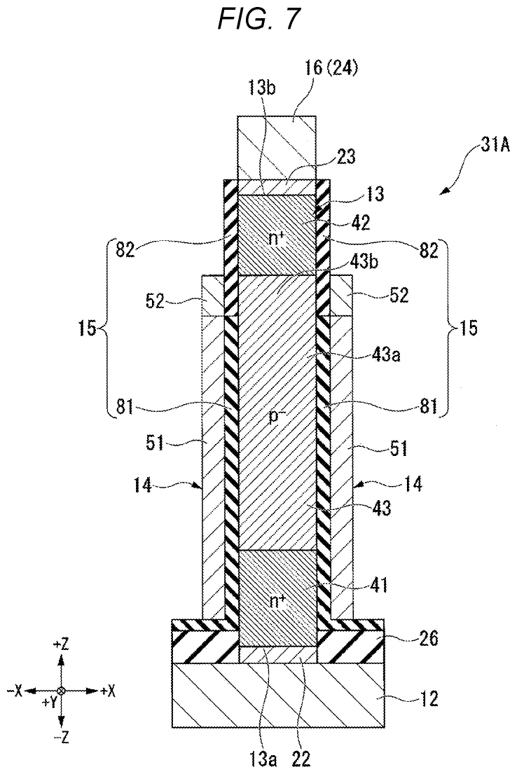

FIG. 7 is a cross-sectional view illustrating a vertical TFT 31A of the second embodiment. The integrated circuit device 1 of at least one embodiment has the vertical TFT 31A instead of the aforementioned vertical TFT 31. The gate insulating film 15 of the vertical TFT 31A has a first insulating portion 81 and a second insulating portion 82.

The first insulating portion 81 faces, in the X direction, a part of the first semiconductor portion 41 and a part of the third semiconductor portion 43 (the first portion 43a of the third semiconductor portion 43). That is, the first insulating portion 81 is provided on a part of the first semiconductor portion 41 and a part of the third semiconductor portion 43. The first insulating portion 81 is made of, for example, silicon oxide (SiO2).

The second insulating portion 82 is provided above the first insulating portion 81. The second insulating portion 82 is provided continuously from the first insulating portion 81 in the Z direction and connected to the first insulating portion 81. The second insulating portion 82 faces, in the X direction, another part of the third semiconductor portion 43 (the second portion 43b of the third semiconductor portion 43) and the second semiconductor portion 42. That is, the second insulating portion 82 is provided on another part of the third semiconductor portion 43 and the second semiconductor portion 42. A part of the second insulating portion 82 is disposed between the second electrode portion 52 of the gate electrode 14 and the third semiconductor portion 43. The second insulating portion 82 is made of, for example, silicon oxynitride (SiON) and has a higher nitrogen concentration than the first insulating portion 81.

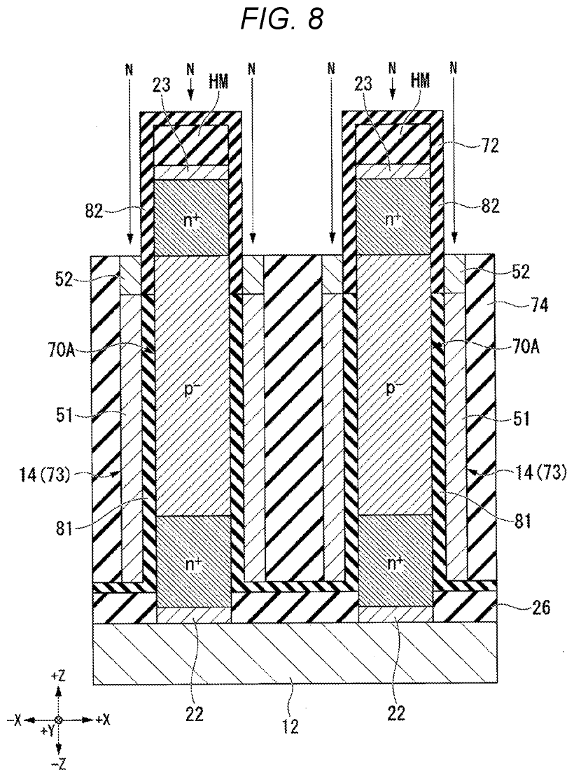

FIG. 8 is a cross-sectional view illustrating a method of manufacturing the vertical TFT 31A of at least one embodiment. The process illustrated in FIG. 8 corresponds to (n) in FIG. 5E of the first embodiment. In at least one embodiment, during the process of introducing nitrogen to the upper portion of the electrode film 73 which becomes the gate electrode 14, the nitrogen is also introduced to the upper portion of the insulating film 72 which becomes the gate insulating film 15. For example, a special additional treatment is not required to introduce the nitrogen to the insulating film 72. That is, the second insulating portion 82 is formed during the process of forming the second electrode portion 52. Further, instead, a special treatment such as a process of implanting ions to the insulating film 72 from an obliquely upper side may be performed in order to promote the formation of the second insulating portion 82.

Here, as a comparative example, a case where the gate insulating film 15 includes no nitrogen is considered. In this case, for example, a portion of the gate insulating film 15, which is located above the gate electrode 14, is shaved and gets thinner by wet etching which is performed after the gate electrode 14 is formed. When the gate insulating film 15 gets thinner, there is a likelihood that a leakage current between the gate electrode 14 and the second semiconductor portion 42 will be increased.

Therefore, in at least one embodiment, nitrogen is also introduced to the upper portion of the gate insulating film 15 during the process of forming the second electrode portion 52 of the gate electrode 14. Therefore, the upper portion of the gate insulating film 15 is made of silicon oxynitride that has higher resistance against etching than silicon oxide. As a result, the gate insulating film 15 hardly gets thinner during the process of manufacturing the integrated circuit device 1, such that it is possible to reduce a leakage current between the gate electrode 14 and the second semiconductor portion 42.

Since a part of the gate insulating film 15 is made of silicon oxynitride, it is possible to improve a dielectric constant of the gate insulating film 15. In at least one embodiment, the second insulating portion 82, which is made of silicon oxynitride, is disposed between the second electrode portion 52 of the gate electrode 14 and the third semiconductor portion 43. According to this configuration, a size of the n-type channel portion CP, which is formed by the second electrode portion 52 of the gate electrode 14, may be increased. Therefore, it is possible to increase the ON current of the vertical TFT 31.

### Third Embodiment

Next, a third embodiment will be described. The third embodiment differs from the first embodiment in that a vertical TFT 31B having a p-type channel is provided. Further, the configurations except for the following configurations are identical to those in the first embodiment.

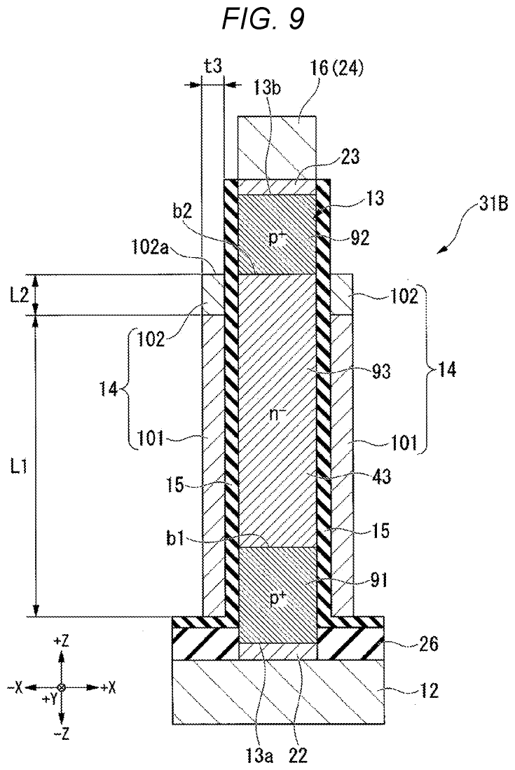

FIG. 9 is a cross-sectional view illustrating the vertical TFT 31B of the third embodiment. The integrated circuit device 1 of at least one embodiment has the vertical TFT 31B having the p-type channel instead of the aforementioned vertical TFT 31.

In at least one embodiment, the silicon member 13 has a first semiconductor portion 91, a second semiconductor portion 92, and a third semiconductor portion 93. The first semiconductor portion 91 includes an impurity which is an acceptor, and the first semiconductor portion 91 is a p type (e.g., p+ type) as a conductivity type. The p type is another example of a “first conductivity type.” The second semiconductor portion 92 includes an impurity which is an acceptor, and the second semiconductor portion 92 is a p type (e.g., p+ type) as a conductivity type. The third semiconductor portion 93 includes an impurity which is a donor, and the third semiconductor portion 93 is an n type (e.g., n− type) as a conductivity type. The n type is another example of a “second conductivity type.” Other configurations and definitions of the first to third semiconductor portions 91, 92, and 93 are approximately the same as those of the first to third semiconductor portions 41, 42, and 43.

In at least one embodiment, the gate electrode 14 has a first electrode portion 101 and a second electrode portion 102. The first electrode portion 101 is made of a third element. In at least one embodiment, the first electrode portion 101 is made of, for example, titanium (Ti) which is an example of the third element.

The second electrode portion 102 includes at least one of nitrogen, oxygen, carbon, or silicon in addition to the third element that forms the first electrode portion 101. That is, the second electrode portion 102 is formed by a composition (compound) created by coupling at least one of nitrogen, oxygen, carbon, and silicon to the third element. In another expression, the second electrode portion 102 has higher concentration of at least one of nitrogen, oxygen, carbon, or silicon than the first electrode portion 101.

In at least one embodiment, the vertical TFT 31B is a p-channel type transistor. In this case, the second electrode portion 102 includes a fourth element that forms a composition, which has a higher work function than the third element, by coupling one of nitrogen, oxygen, carbon, or silicon to the third element. For example, in a case where the third element is titanium, an example of the fourth element is nitrogen. In this case, the second electrode portion 102 is made of titanium nitride (TiN).

In at least one embodiment, the second electrode portion 102 does not overlap, in the X direction, the second semiconductor portion 92. That is, an upper end 102a of the second electrode portion 102 is located at approximately the same position in the Z direction as the boundary b2 between the third semiconductor portion 93 and the second semiconductor portion 92 or located below the boundary b2. Other configurations and definitions of the first and second electrode portions 101 and 102 are approximately the same as those of the first and second electrode portions 51 and 52.

According to this configuration, when a voltage is applied to the gate electrode 14, the second electrode portion 102 comes into the ON state first in comparison with the first electrode portion 101, and a p-type channel portion is formed by the second electrode portion 102. In at least one embodiment, since the second electrode portion 102 has a higher work function than the first electrode portion 101, the p-type channel, which is connected to the second semiconductor portion 92, may be formed even in the case where the width of the gate electrode 14, which overlaps the second semiconductor portion 92, is small or the gate electrode 14 does not overlap the second semiconductor portion 92. Therefore, it is possible to inhibit a decrease in ON current of the vertical TFT 31B.

While several embodiments have been described above, the embodiments are not limited to the aforementioned examples. For example, a combination of the first to third embodiments may be implemented. For example, in the vertical TFT 31B of the third embodiment, the gate insulating film 15 may have the first insulating portion 81 and the second insulating portion 82.

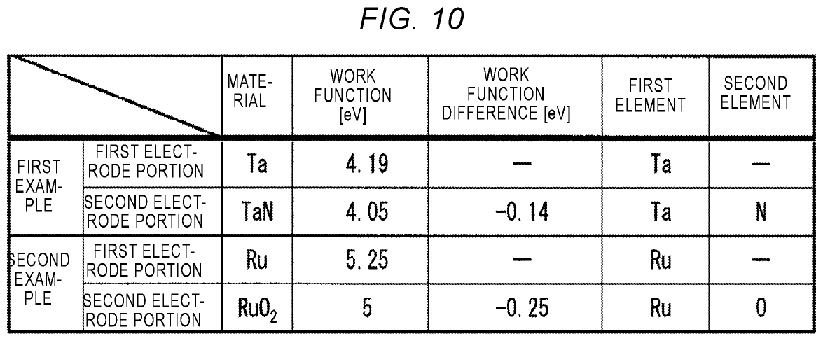

In at least one embodiment, the example of (tantalum:nitrogen) has been described as a combination (first element:second element) of materials of the gate electrode 14 in the case where the vertical TFT 31 having the n-type channel is formed. However, the combination of (first element:second element) is not limited to the aforementioned example, and a combination of (ruthenium:oxygen) or the like may be applied. In a case where the combination of (ruthenium:oxygen) is used, the first electrode portion 51 is made of ruthenium (Ru), and the second electrode portion 52 is made of ruthenium oxide (RuO2). Examples of the combinations of the first element and the second element are illustrated in an organized manner in FIG. 10. In FIG. 10, the term “work function difference” means a difference in work function between the second electrode portion 52 and the first electrode portion 51.

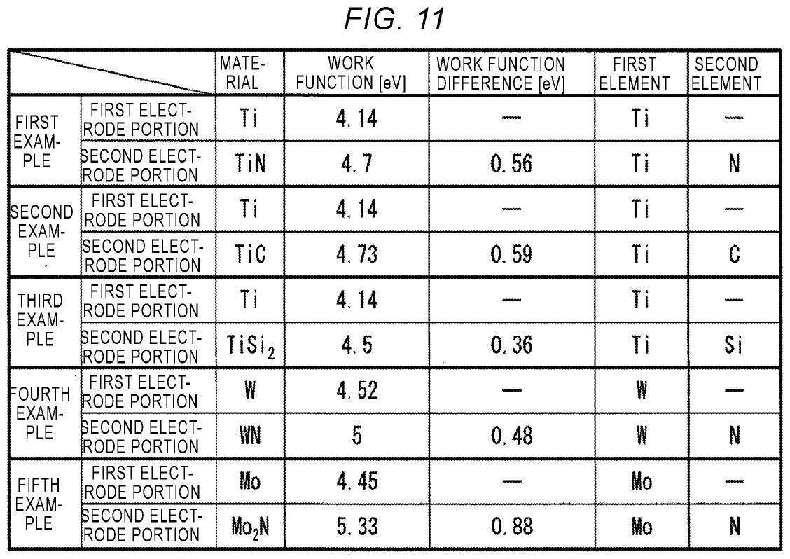

In at least one embodiment, the example of (titanium:nitrogen) has been described as a combination (third element:fourth element) of materials of the gate electrode 14 in the case where the vertical TFT 31B having the p-type channel is formed. However, the combination of (third element:fourth element) is not limited to the aforementioned example, and combinations of (titanium:carbon), (titanium silicon), (tungsten nitrogen), (molybdenum:nitrogen), and the like may be applied. In a case where the combination of (titanium:carbon) is used, the first electrode portion 101 is made of titanium, and the second electrode portion 102 is made of titanium carbide (TiC). In a case where the combination of (titanium:silicon) is used, the first electrode portion 101 is made of titanium, and the second electrode portion 102 is made of titanium silicide (TiSi₂). In a case where the combination of (tungsten:nitrogen) is used, the first electrode portion 101 is made of tungsten (W), and the second electrode portion 102 is made of tungsten nitride (WN). In a case where the combination of (molybdenum:nitrogen) is used, the first electrode portion 101 is made of molybdenum (Mo), and the second electrode portion 102 is made of molybdenum nitride (Mo₂N). Examples of the combinations of the third element and the fourth element are arranged and illustrated in FIG. 11. In FIG. 11, the term “work function difference” means a difference in work function between the second electrode portion 102 and the first electrode portion 101.

According to at least one of the aforementioned embodiments, the second electrode portion, which has concentration of at least one of nitrogen, oxygen, carbon, and silicon which is different from that of the first electrode portion, is provided, and as a result, it is possible to improve electrical characteristics of the integrated circuit device.

Hereinafter, several integrated circuit devices will be additionally described.

[1] An integrated circuit device comprising:

a first wiring;

a second wiring;

a first semiconductor portion electrically connected to the first wiring and having a first conductivity type;

a second semiconductor portion electrically connected to the second wiring and having the first conductivity type;

a third semiconductor portion provided between the first semiconductor portion and the second semiconductor portion and having a second conductivity type;

a first insulating film provided on at least a part of the first semiconductor portion, at least a part of the second semiconductor portion, and the third semiconductor portion; and

an electrode including a first electrode portion provided on a part of the third semiconductor portion with the first insulating film interposed between the first electrode portion and the third semiconductor portion, and a second electrode portion electrically connected to the first electrode portion, the second electrode portion positioned adjacent the second semiconductor portion, the second electrode portion provided on another part of the third semiconductor portion with the first insulating film interposed between the second electrode portion and the another part of the third semiconductor portion, and the second electrode portion having a concentration of at least one of nitrogen, oxygen, carbon, or silicon that is different from that of the first electrode portion.

[2] The integrated circuit device according to [1], wherein the second electrode portion has a higher concentration of at least one of nitrogen, oxygen, carbon, or silicon than that of the first electrode portion.

[3] The integrated circuit device according to [1], wherein the first electrode portion and the second electrode portion include tantalum, and the second electrode portion has a higher nitrogen concentration than that of the first electrode portion.

[4] The integrated circuit device according to [1], wherein the first electrode portion and the second electrode portion include ruthenium, and the second electrode portion has a higher oxygen concentration than that of the first electrode portion.

[5] The integrated circuit device according to [1], wherein the first electrode portion and the second electrode portion include titanium, and

the second electrode portion has at least one of a nitrogen concentration, a carbon concentration, or a silicon concentration that is higher than that of the first electrode portion.

[6] The integrated circuit device according to [1], wherein the first electrode portion and the second electrode portion include tungsten, and

the second electrode portion has a higher nitrogen concentration than that of the first electrode portion.

[7] The integrated circuit device according to [1], wherein the first electrode portion and the second electrode portion include molybdenum, and

the second electrode portion has a higher nitrogen concentration than that of the first electrode portion.

[8] The integrated circuit device according to [1], wherein the second electrode portion does not overlap the second semiconductor portion in a second direction approximately orthogonal to a first direction from the first semiconductor portion to the second semiconductor portion.

[9] The integrated circuit device according to [1], wherein a length of the second electrode portion in a first direction from the first semiconductor portion toward the second semiconductor portion is shorter than a length of the first electrode portion in the first direction.

[10] The integrated circuit device according to [9], wherein the length of the second electrode portion in the first direction is equal to or shorter than a half of the length of the first electrode portion in the first direction.

[11] The integrated circuit device according to [1], in which a length of the second electrode portion in a first direction from the first semiconductor portion toward the second semiconductor portion is greater than a thickness of the second electrode portion in a second direction approximately orthogonal to the first direction.

[12] The integrated circuit device according to [1], wherein a thickness of the second semiconductor portion in a first direction from the first semiconductor portion toward the second semiconductor portion is smaller than a thickness of the first semiconductor portion in the first direction.

[13] The integrated circuit device according to [1], further including:

a substrate; and

a stacked body in which a plurality of third wirings and a plurality of second insulating films are alternately stacked,

wherein the first electrode portion and the second electrode portion are located between the substrate and the stacked body, and

the second electrode portion is located adjacent the stacked body.

[14] The integrated circuit device according to [13], wherein the plurality of third wirings and the plurality of second insulating films are alternately stacked in a first direction from the first semiconductor portion toward the second semiconductor portion.

[15] The integrated circuit device according to [13], wherein the first electrode portion overlaps at least a part of the first semiconductor portion with the first insulating film interposed between the first electrode portion and the the first semiconductor portion.

[16] The integrated circuit device according to [1], wherein the first insulating film includes a first insulating portion provided on the third semiconductor portion, and a second insulating portion provided on the second semiconductor portion, and

the second insulating portion has a higher nitrogen concentration than that of the first insulating portion.

[17] The integrated circuit device according to [16], wherein a part of the second insulating portion is located between the second electrode portion and the third semiconductor portion.

[18] The integrated circuit device according to [1], wherein the second wiring extends in a first direction from the first semiconductor portion toward the second semiconductor portion, the first wiring extends in a second direction intersecting the first direction, and the first electrode portion and the second electrode portion extend in a third direction intersecting the first direction and the second direction.

[19] The integrated circuit device according to [14], wherein the second wiring extends in the first direction, the first wiring extends in a second direction intersecting the first direction, and the first electrode portion and the second electrode portion extend in a third direction intersecting the first direction and the second direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit, of the inventions. The accompanying claims and their equivalents are intended to cover such forms or modifications as would fall within the scope and spirit of the inventions.

What is claimed is:

1. An integrated circuit device comprising:
a first wiring;
a second wiring;
a first semiconductor portion electrically connected to the first wiring and having a first conductivity type;
a second semiconductor portion electrically connected to the second wiring and having the first conductivity type;
a third semiconductor portion provided between the first semiconductor portion and the second semiconductor portion and having a second conductivity type;
an insulating film provided on at least a part of the first semiconductor portion, at least a part of the second semiconductor portion, and the third semiconductor portion; and
an electrode including a first electrode portion provided on a part of the third semiconductor portion with the first insulating film interposed between the first electrode portion and the third semiconductor portion, and a second electrode portion electrically connected to the first electrode portion, the second electrode portion positioned adjacent the second semiconductor portion, the second electrode portion provided on another part of the third semiconductor portion with the first insulating film interposed between the second electrode portion and the another part of the third semiconductor portion, and the second electrode portion having a concentration of at least one of nitrogen, oxygen, carbon, or silicon that is different from that of the first electrode portion.

2. The integrated circuit device according to claim 1, wherein the first electrode portion and the second electrode portion include tantalum, and
the second electrode portion has a higher nitrogen concentration than that of the first electrode portion.

3. The integrated circuit device according to claim 1, wherein the first electrode portion and the second electrode portion include at least one of tungsten, titanium, or molybdenum, and
the second electrode portion has a higher nitrogen concentration than that of the first electrode portion.

4. The integrated circuit device according to claim 1, wherein the second electrode portion does not overlap the second semiconductor portion in a second direction approximately orthogonal to a first direction from the first semiconductor portion toward the second semiconductor portion.

5. The integrated circuit device according to claim 1, wherein the insulating film includes a first insulating portion provided on the third semiconductor portion, and a second insulating portion provided on the second semiconductor portion, and
the second insulating portion has a higher nitrogen concentration than that of the first insulating portion.

6. The integrated circuit device according to claim 1, wherein the second electrode portion has a higher concentration of at least one of nitrogen, oxygen, carbon, or silicon than that of the first electrode portion.

7. The integrated circuit device according to claim 1, wherein the first electrode portion and the second electrode portion include ruthenium, and the second electrode portion has a higher oxygen concentration than that of the first electrode portion.

8. The integrated circuit device according to claim 1, wherein the first electrode portion and the second electrode portion include titanium, and
the second electrode portion has at least one of a nitrogen concentration, a carbon concentration, or a silicon concentration that is higher than that of the first electrode portion.

9. The integrated circuit device according to claim 1, wherein the first electrode portion and the second electrode portion include tungsten, and
the second electrode portion has a higher nitrogen concentration than that of the first electrode portion.

10. The integrated circuit device according to claim 1, wherein the first electrode portion and the second electrode portion include molybdenum, and
the second electrode portion has a higher nitrogen concentration than that of the first electrode portion.

11. The integrated circuit device according to claim 1, wherein a length of the second electrode portion in a first direction from the first semiconductor portion toward the second semiconductor portion is shorter than a length of the first electrode portion in the first direction.

12. The integrated circuit device according to claim 11, wherein the length of the second electrode portion in the first direction is equal to or shorter than a half of the length of the first electrode portion in the first direction.

13. The integrated circuit device according to claim 1, in which a length of the second electrode portion in a first direction from the first semiconductor portion toward the second semiconductor portion is greater than a thickness of the second electrode portion in a second direction approximately orthogonal to the first direction.

14. The integrated circuit device according to claim 1, wherein a thickness of the second semiconductor portion in a first direction from the first semiconductor portion toward the second semiconductor portion is smaller than a thickness of the first semiconductor portion in the first direction.

15. The integrated circuit device according to claim 1, further including:
a substrate; and
a stacked body in which a plurality of third wirings and a plurality of second insulating films are alternately stacked,
wherein the first electrode portion and the second electrode portion are located between the substrate and the stacked body, and
the second electrode portion is located adjacent the stacked body.

16. The integrated circuit device according to claim 15, wherein the plurality of third wirings and the plurality of second insulating films are alternately stacked in a first direction from the first semiconductor portion toward the second semiconductor portion.

17. The integrated circuit device according to claim 15, wherein the first electrode portion overlaps at least a part of the first semiconductor portion with the first insulating film interposed between the first electrode portion and the the first semiconductor portion.

18. The integrated circuit device according to claim 5, wherein a part of the second insulating portion is located between the second electrode portion and the third semiconductor portion.

19. The integrated circuit device according to claim 1, wherein the second wiring extends in a first direction from the first semiconductor portion toward the second semiconductor portion, the first wiring extends in a second direction intersecting the first direction, and the first electrode portion and the second electrode portion extend in a third direction intersecting the first direction and the second direction.

20. The integrated circuit device according to claim 16, wherein the second wiring extends in the first direction, the first wiring extends in a second direction intersecting the first direction, and the first electrode portion and the second electrode portion extend in a third direction intersecting the first direction and the second direction.
